(19) United States
(12) Patent Application Publication
(10) Pub. No.: US 2019/0088596 A1
(43) Pub. Date: Mar. 21, 2019

(54) E-FUSE FOR USE IN SEMICONDUCTOR DEVICE

(71) Applicants: SK hynix Inc., Gyeonggi-do (KR); INDUSTRY-ACADEMIA COOPERATION GROUP OF SEJONG UNIVERSITY, Seoul (KR)

(72) Inventors: Deok-kee KIM, Seoul (KR); Honggyun KIM, Seoul (KR); Jae Hong KIM, Gyeonggi-do (KR); Seo Woo NAM, Gyeonggi-do (KR)

(21) Appl. No.: 15/896,593

(22) Filed: Feb. 14, 2018

(30) Foreign Application Priority Data
Sep. 18, 2017 (KR) 10-2017-0119311

(51) Int. Cl. H01L 23/525; H01L 27/06; H01L 27/02

(52) U.S. Cl. CPC H01L 23/5256; H01L 27/0285; H01L 27/0629

(57) ABSTRACT

An e-fuse for use in a semiconductor device includes first and second electrodes; a gate metal electrically coupling the first and second electrodes with each other; a semiconductor layer formed under the gate metal, and formed with a drain region and a source region in a top thereof corresponding to both sides of the gate metal to form a transistor together with the gate metal; and a first oxide layer formed under the gate metal and on both sides of the semiconductor layer.

### CROSS-REFERENCES TO RELATED APPLICATION

The present application claims priority under 35 U.S.C. § 119(a) to Korean application number 10-2017-0119311, filed on Sep. 18, 2017, which is herein incorporated by reference in its entirety.

### BACKGROUND

### 1. Technical Field

Various embodiments generally relate to an e-fuse for use in a semiconductor device and a semiconductor device comprising the same.

### 2. Related Art

In general, semiconductor device fuse circuits are used to achieve various purposes in the field of semiconductor technology. For example, fuses may be used in a repair process in which a failed memory cell is replaced with a redundancy memory cell, and may be used in a constant voltage generation circuit which tunes a voltage or a control circuit for selecting various modes and testing.

Such fuses may be divided into laser fuses and e-fuses depending on a cutting method. Between them, the e-fuses use a method of selectively cutting them by using current. Meanwhile, one of the requirements for improved fuse technology is to reduce the fuse area. In this regard, since a selection element provides program current and occupies most of the fuse area, it may be required a technique for lowering program current affecting the size of the selection element to thereby reduce the fuse area.

### SUMMARY

Various embodiments are directed to an e-fuse for use in a semiconductor device capable of being blown with low program current, thereby improving performance and reducing a fuse area.

In an embodiment, an e-fuse for use in a semiconductor device may include: first and second electrodes; a gate metal electrically coupling the first and second electrodes with each other; a semiconductor layer formed under the gate metal, and formed with a drain region and a source region in a top thereof corresponding to both sides of the gate metal to form a transistor together with the gate metal; and a first oxide layer formed under the gate metal and on both sides of the semiconductor layer.

In an embodiment, an e-fuse for use in a semiconductor device may include: first and second electrodes; a gate metal electrically coupling the first and second electrodes with each other; a semiconductor layer formed under the gate metal, and formed with a drain region and a source region in a top thereof corresponding to both sides of the gate metal to form a transistor together with the gate metal; and a first oxide layer formed under a bottom end of the gate metal and on both sides of the semiconductor layer, wherein the gate metal includes a first gate metal extending from the first electrode and a second gate metal extending from the second electrode to be brought into contact with the first gate metal, and wherein the first and second gate metals are formed of different metals.

In an embodiment, A semiconductor device comprising a plurality of e-fuses, each of the e-fuses comprising: first and second electrodes; a gate metal electrically coupling the first and second electrodes with each other; a semiconductor layer formed under the gate metal, and formed with a drain region and a source region in a top thereof corresponding to both sides of the gate metal to form a transistor together with the gate metal; and a first oxide layer formed under the gate metal and on both sides of the semiconductor layer.

According to the embodiments, since a characteristic of a transistor may be changed by applying relatively low program current, it is possible to improve the performance of the e-fuse.

Also, since blowing is possible with low program current, it is possible to reduce an area per bit of the e-fuse.

### BRIEF DESCRIPTION OF THE DRAWINGS

FIG. 1 is a top view to assist in the explanation of an e-fuse for use in a semiconductor device in accordance with a first embodiment of the present disclosure.

FIG. 2 is a cross-sectional view taken along the line I-I′ of FIG. 1.

FIG. 3 is a cross-sectional view taken along the line II-II′ of FIG. 1.

FIG. 4 is a view to assist in the explanation of the change of drain current when programming the e-fuse.

FIG. 5 is a graph to assist in the explanation of the change of drain current before and after program.

FIGS. 6 and 7 are views to assist in the explanation of the change of gate current and substrate current when programming the e-fuse.

FIG. 8 is a top view to assist in the explanation of an e-fuse for use in a semiconductor device in accordance with a second embodiment of the present disclosure.

FIG. 9 is a cross-sectional view taken along the line I-I′ of FIG. 8.

FIG. 10 is a top view to assist in the explanation of an e-fuse for use in a semiconductor device in accordance with a third embodiment of the present disclosure.

FIG. 11 is a cross-sectional view taken along the line I-I′ of FIG. 10.

FIG. 12 is a top view to assist in the explanation of an e-fuse for use in a semiconductor device in accordance with a fourth embodiment of the present disclosure.

FIG. 13 is a cross-sectional view taken along the line I-I′ of FIG. 12.

FIG. 14 is a top view to assist in the explanation of an e-fuse for use in a semiconductor device in accordance with a fifth embodiment of the present disclosure.

FIG. 15 is a cross-sectional view taken along the line I-I′ of FIG. 14.

FIG. 16 is a top view to assist in the explanation of an e-fuse for use in a semiconductor device in accordance with a sixth embodiment of the present disclosure.

FIG. 17 is a cross-sectional view taken along the line I-I′ of FIG. 16.

FIG. 18 is a top view to assist in the explanation of an e-fuse for use in a semiconductor device in accordance with a seventh embodiment of the present disclosure.

FIG. 19 is a cross-sectional view taken along the line I-I′ of FIG. 18.

### DETAILED DESCRIPTION

Hereinafter, various embodiments will be described in detail with reference to the accompanying drawings to the extent that a person skilled in the art to which the embodiments pertain may easily enforce the embodiments. Among the reference numerals presented in the drawings, like reference numerals denote like members.

In describing the present disclosure, when it is determined that the detailed description of the known related art may obscure the gist of the present disclosure, the detailed description thereof will be omitted.

Although terms such as first and second may be used to describe various components, the components are not limited by the terms, and the terms are used only to distinguish components from other components.

In the following embodiments, an n-type metal may be defined as a metal which is used in an NMOS (n-type metal oxide semiconductor) transistor, and a p-type metal may be defined as a metal which is used in a PMOS (p-type metal oxide semiconductor) transistor.

FIG. 1 is a top view to assist in the explanation of an e-fuse for a semiconductor device in accordance with a first embodiment of the present disclosure.

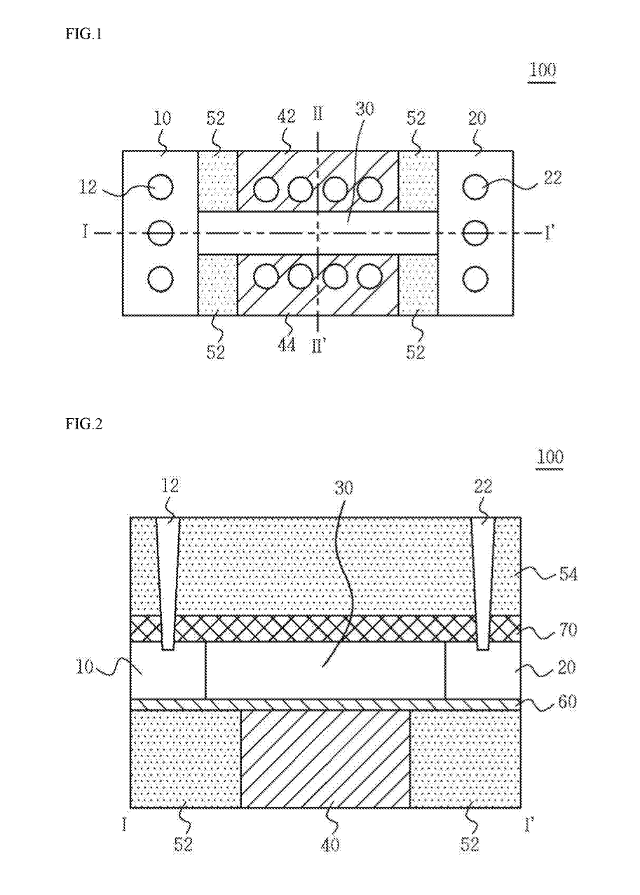

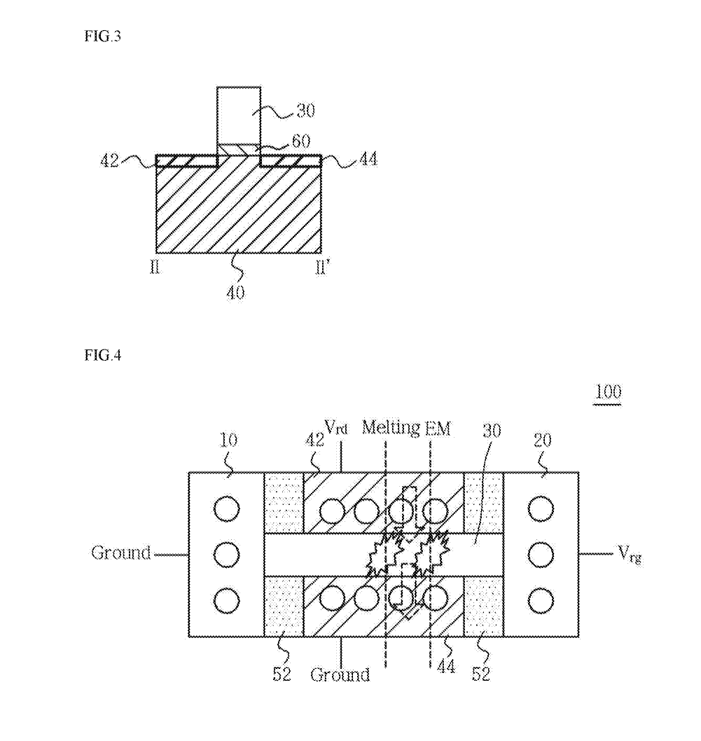

Referring to FIG. 1, an e-fuse 100 of a semiconductor device includes first and second electrodes 10 and 20, a gate metal 30, a semiconductor layer 40 (see FIG. 2) which is formed with a drain region 42 and a source region 44, and a first oxide layer 52.

The first electrode 10 may be referred to as a cathode, and the second electrode 20 may be referred to as an anode. Contacts 12 and 22 for applying a program voltage may be formed on the first and second electrodes 10 and 20. Programming the e-fuse may include flowing a program current through the gate metal 30 by applying a program voltage to any one of the first and second electrodes 10 and 20 and applying a ground voltage to the other of the first and second electrodes 10 and 20.

The gate metal 30 has a structure which electrically couples the first and second electrodes 10 and 20 between the first and second electrodes 10 and 20, and is formed of a material capable of being electrically programmed. For instance, the gate metal 30 may be formed of a metal which has a work function appropriate for an NMOS or a PMOS. The gate metal 30 may be formed of a metallic material such as Al or may be formed of layers of TiN, Ti, Al and AITiO. The gate metal 30 may be formed integrally with the first electrode 10 and the second electrode 20. The gate metal 30 may have the shape of an elongated bar extending in a first direction I-I′. The first and second electrodes 10 and 20 may each have the shape of an elongated bar extending in a second direction II-II′. The second direction I-I′ may be perpendicular to the first direction II-II′.

The semiconductor layer 40 is formed under the gate metal 30 and a gate dielectric 60 is disposed therebetween. The semiconductor layer may have a smaller length in the first direction I-I′ than the gate metal 30. The semiconductor layer 40 may be formed of silicon. The drain region 42 is formed in the top of the semiconductor layer 40 corresponding to one side of the gate metal 30, and the source region 44 is formed in the top of the semiconductor layer 40 corresponding to the other side of the gate metal 30. The drain region 42 and the source region 44 are formed in the top of the semiconductor layer 40 corresponding to both sides of the gate metal 30 in such a way as to be separated from each other.

The gate metal 30 and the semiconductor layer 40 which is formed with the drain and source regions 42 and 44 may form a transistor. The gate metal 30 and the semiconductor layer 40 may form an n-type or a p-type transistor. In the case where the gate metal 30, the drain region 42 and the source region 44 are formed in an n-type, a negative voltage (or the ground voltage) may be applied to the first electrode 10 and a positive voltage (or the program voltage) may be applied to the second electrode 20. In the case where the gate metal 30, the drain region 42 and the source region 44 are formed in a p-type, a positive voltage (or the program voltage) may be applied to the first electrode 10 and a negative voltage (or the ground voltage) may be applied to the second electrode 20. Alternatively, regardless of whether the gate metal 30, the drain region 42 and the source region 44 form an NMOS or a PMOS transistor, a negative voltage may be applied to a cathode and a positive voltage may be applied to an anode in such a manner that the gate metal 30 is cut by being programmed.

The first oxide layer 52 is formed on both sides of the semiconductor layer 40 at the same level as the semiconductor layer 40.

As such, the e-fuse 100 of a semiconductor device includes the first and second electrodes 10 and 20 for applying the program voltage, the gate metal 30 which electrically couples the first and second electrodes 10 and 20, the drain region 42 and the source region 44 which are formed on both sides of the gate metal 30 to be separated from each other, the semiconductor layer 40 (see FIG. 2) which is formed under the first and second electrodes 10 and 20 and the gate metal 30, the first oxide layer 52 which is formed under the first and second electrodes 10 and 20 and on both sides of the semiconductor layer 40, and the gate dielectric 60 which is disposed below the gate metal 30 and the first and second electrodes 10 and 20 and above the first oxide layer 52 and the semiconductor layer 40.

In the e-fuse 100 of a semiconductor device configured as mentioned above, when a the program voltage is applied to the first and second electrodes 10 and 20, a program current flows through the gate metal 30 due to the potential difference of the first and second electrodes 10 and 20, and electro-migration, thermo-migration and melting phenomena are induced in the gate metal 30 by the program current. As a result, a void may be formed in the gate metal 30 and resistance may increase.

Also, in the e-fuse 100 of a semiconductor device, the gate metal 30 and a gate oxide layer 60 (see FIG. 2) may react with each other or the dielectric constant characteristic of the gate oxide layer 60 may change due to the high temperature of the gate metal 30 in the program. Through this, the drain current, gate current and substrate current of the e-fuse 100 having the structure of an NMOS or a PMOS transistor may significantly change before and after the programming.

A driving force by the electro-migration induced in the gate metal 30 may be changed by changing the sectional area of the gate metal 30. While it is illustrated in FIG. 1 that the gate metal 30 has the same sectional area between the first and second electrodes 10 and 20 and extends in one direction, this is only for the sake of convenience in explanation, and it is to be noted that the embodiment is not limited thereto. The gate metal 30 may include a bent portion in correspondence to the positions of the first and second electrodes 10 and 20, and may be formed to have a different sectional area.

When the program current flows through the gate metal 30, Joule's heat may be generated in the gate metal 30. The Joule's heat induced by the program current may have a nonuniform temperature distribution in the gate metal 30. The non-uniform temperature distribution in the gate metal 30 may have a highest temperature at the center portion of the gate metal 30. The nonuniform temperature distribution may induce the thermo-migration of atoms in the gate metal 30. The thermo-migration may include a thermo-migration in which atoms migrate in an anode direction from the center portion of the gate metal 30 and a thermo-migration in which atoms migrate in a cathode direction from the center portion of the gate metal 30.

In this way, when the program current flows through the gate metal 30, electro-migration, thermo-migration and melting phenomena are induced in the gate metal 30, and a driving force by the electro-migration and thermo-migration phenomena blows the gate metal 30. If the gate metal 30 is blown, the drain current, gate current and substrate current flowing through the e-fuse 100 of the transistor structure may significantly change before and after the programming. As a consequence, the performance of the e-fuse 100 may be improved since a high on/off ratio is possible due to the many more changes occurring when compared to an e-fuse constituted by only a metal line, and an area per bit of the e-fuse 100 may be reduced since the program is possible with low current.

A silicon nitride layer 70 and a second oxide layer 54 shown in FIG. 2 are not shown in the top view of FIG. 1 to facilitate the understanding of the structure of the present embodiment. As shown in FIG. 2, the silicon nitride layer 70 may be formed on the gate metal 30 and the first and second electrodes 10 and 20, and the second oxide layer 54 may be formed on the silicon nitride layer 70, the semiconductor layer 40 and the first oxide layer 52.

FIG. 2 is a cross-sectional view taken along the line I-I′ of FIG. 1.

Referring to FIG. 2, the e-fuse 100 of a semiconductor device includes the semiconductor layer 40, the first oxide layer 52 which is formed on both sides of the semiconductor layer 40, the gate metal 30 which couples the first and second electrodes 10 and 20 and the gate oxide layer 60.

The gate oxide layer 60 is formed under the gate metal 30. The gate oxide layer 60 is formed to be brought into contact with the semiconductor layer 40 corresponding to the bottom end of the gate metal 30. And the gate oxide layer 60 is formed to be brought into contact with the top end of the first oxide layer 52 corresponding to the bottom end of the gate metal 30. The gate oxide layer 60 may also be formed between the bottom end of the first and second electrodes 10 and 20 and the top end of the first oxide layer 52 corresponding to the bottom end of the first and second electrodes 10 and 20. The gate oxide layer 60 may react with the gate metal 30 or be changed in its dielectric constant characteristic due to a high temperature in the program. For instance, the gate oxide layer 60 may be formed of HfO₂.

The silicon nitride layer 70 may be formed on the gate metal 30 and the first and second electrodes 10 and 20, and the second oxide layer 54 is formed on the silicon nitride layer 70. For instance, the silicon nitride layer 70 may be formed of SiN or SiCN. Contacts 12 and 22 for applying the program voltage and the ground voltage to the first and second electrodes 10 and 20 in the program may be formed in the silicon nitride layer 70 and the second oxide layer 54 corresponding to the tops of the first and second electrodes 10 and 20.

FIG. 3 is a cross-sectional view taken along the line II-II′ of FIG. 1. The silicon nitride layer 70 shown in FIG. 2 is not shown in the cross-sectional view of FIG. 3. As shown in FIG. 2, the silicon nitride layer 70 may be formed on the gate metal 30, and the second oxide layer 54 may be formed on the silicon nitride layer 70 and the semiconductor layer 40.

Referring to FIG. 3, the e-fuse 100 of a semiconductor device includes the gate metal 30, and the semiconductor layer 40 which is formed under the gate metal 30 and in which the drain and source regions 42 and 44 are formed in the top surface of the semiconductor layer 40 corresponding to both sides of the gate metal 30 to be separated from each other. In this way, in the present embodiment, the e-fuse 100 of a semiconductor device may be formed as a transistor. By forming the drain region 42 and the source region 44 in the n-type or the p-type, the e-fuse 100 may be formed as an n-type or a p-type transistor.

The gate oxide layer 60 may be formed between the gate metal 30 and the semiconductor layer 40. By the heat generated in the program, the gate oxide layer 60 may be changed in its characteristic or may react with the gate metal 30 and thus be changed in its dielectric constant characteristic. As a result, the gate oxide layer 60 may break down.

FIG. 4 is a view to assist in the explanation of the change of the drain current when programming the e-fuse 100. FIG. 5 is a graph to assist in the explanation of the change of the drain current before and after the programming. For instance, FIGS. 4 and 5 exemplify a case where the gate metal 30, the drain region 42 and the source region 44 are formed into an NMOS type transistor structure, and the ground voltage is applied to the first electrode 10 and the program voltage is applied to the second electrode 20.

Referring to FIGS. 4 and 5, in the e-fuse 100 of a semiconductor device, when the program voltage is applied to the first and second electrodes 10 and 20, the program current flows through the gate metal 30 due to the potential difference of the first and second electrodes 10 and 20, and the electro-migration, thermo-migration and melting phenomena are induced in the gate metal 30 by the program current. As a result, a void may be formed in the gate metal 30 and resistance may increase.

In the case where fusing proceeds in a state where a current density is relatively high in the program of the e-fuse 100, a void may be formed in the center of the gate metal 30 by the melting of the middle portion of the gate metal 30. In the case where fusing proceeds in a state where a current density is relatively low in the program of the e-fuse 100, a void may be formed in a portion of the gate metal 30 close to the second electrode 20 by the electro-migration and thermo-migration.

In this regard, the drain current shows a large difference before and after the programming as one or more of the following phenomena apply.

First, if the gate metal 30 is programmed, since the width of the transistor becomes smaller, the drain current decreases in comparison with before the program. Moreover, if the gate metal 30 is programmed, since the gate resistance of the transistor increases and thus a voltage actually applied to a gate decreases, the drain current decreases.

Further, since the characteristic of the oxide of the transistor is changed by the heat generated in the program of the gate metal 30, the drain current changes due to a change in the Vth value of the transistor.

In addition, if the gate metal 30 is programmed, since the thickness of a portion in which a void may be formed is changed or the characteristic of the metal is changed by the program heat, a work function, Vth and so forth change, and the drain current flowing through the transistor changes.

In this way, in the e-fuse 100, the amount of the drain current changes due to the change in the width of the transistor, the increase in the resistance of the gate metal 30 and changes in a work function and so forth, depending on whether the program is performed or not.

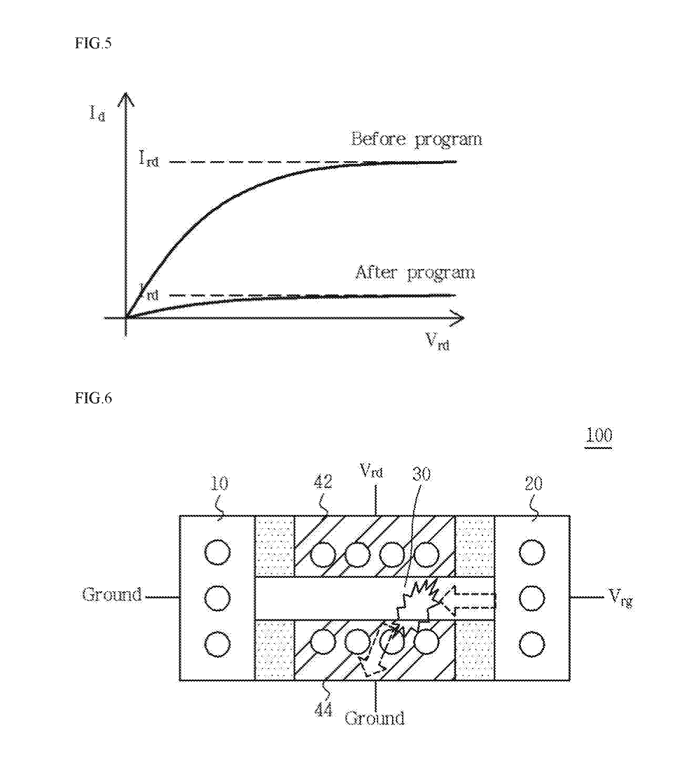

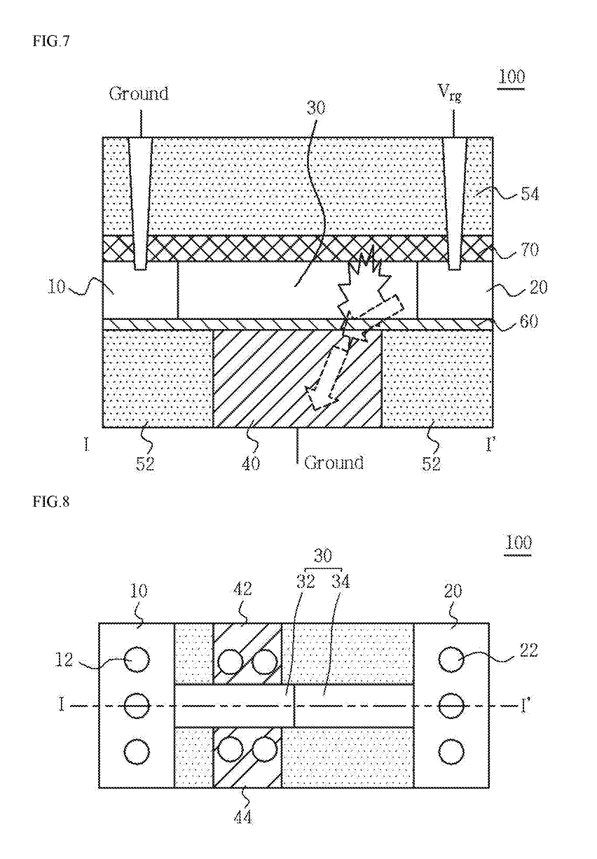

FIGS. 6 and 7 are views to assist in the explanation of the change of the gate current and the substrate current when programming the e-fuse.

Referring to FIGS. 6 and 7, in the e-fuse 100 of a semiconductor device, when the program voltage is applied to the first and second electrodes 10 and 20, the program current flows through the gate metal 30 due to the potential difference of the first and second electrodes 10 and 20, and electro-migration, thermo-migration and melting phenomena are induced in the gate metal 30 by the program current. As a result, a void may be formed in the gate metal 30 and resistance may increase.

In this regard, the gate current and the substrate current show large differences before and after the programming, for the reasons set forth below.

First, by the heat generated in the programming of the gate metal 30, the gate metal 30 and the gate oxide layer 60 of the transistor are changed in their characteristics or react with each other, whereby the dielectric constant characteristic of the gate oxide layer 60 is changed and thus leakage current increases. As a result, the gate current and the substrate current increase.

Also, in the case where excessive current flows through the gate metal 30 in the program of the gate metal 30, a breakdown may occur in the gate oxide layer 60, and as a result, as the gate metal 30 and the semiconductor layer 40 are short-circuited, the gate current and the substrate current significantly increase.

In this way, in the e-fuse 100, the amounts of the gate current and the substrate current change due to the changes in the characteristics of the gate metal 30 and the gate oxide layer 60 and the breakdown of the gate oxide layer 60, depending on whether or not the program is performed.

FIG. 8 is a top view to assist in the explanation of an e-fuse 100 of a semiconductor device in accordance with a second embodiment of the present disclosure. FIG. 9 is a cross-sectional view taken along the line I-I′ of FIG. 8. A silicon nitride layer 70 and a second oxide layer 54 shown in FIG. 9 are not shown in the top view of FIG. 8 to facilitate the understanding of the structure of the present embodiment. As shown in FIG. 9, the silicon nitride layer 70 may be formed on gate metal 30 and first and second electrodes 10 and 20, and the second oxide layer 54 may be formed on the silicon nitride layer 70, the semiconductor layer 40 and the first oxide layer 52.

Referring to FIGS. 8 and 9, the e-fuse 100 of a semiconductor device includes the first and second electrodes 10 and 20, the gate metal 30, the semiconductor layer 40 which is formed with the drain region 42 and the source region 44, the first oxide layer 52, and the gate oxide layer 60.

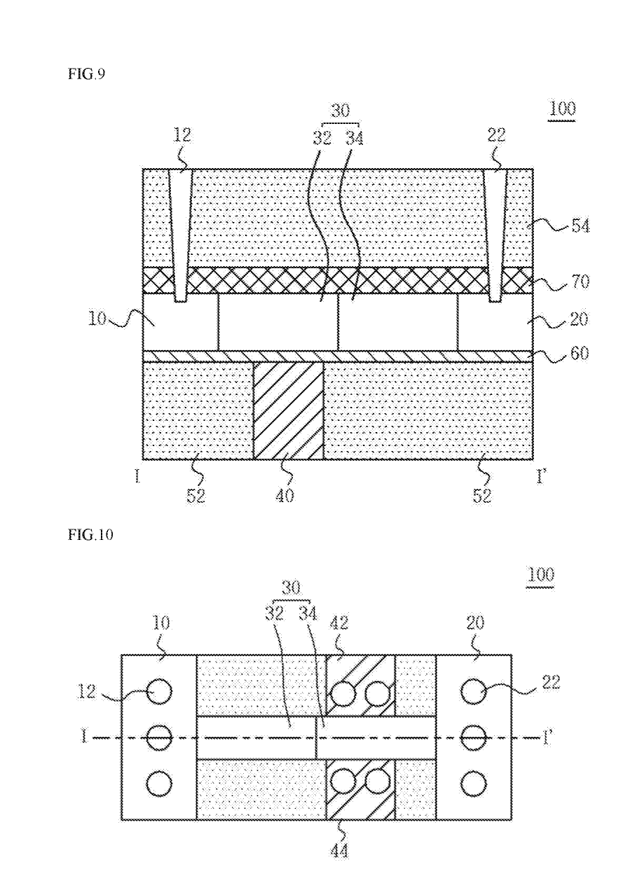

The gate metal 30 which couples the first and second electrodes 10 and 20 includes a first gate metal 32 which extends from the first electrode 10 toward the second electrode 20 and a second gate metal 34 which extends from the second electrode 20 toward the first electrode 10. The first and second gate metals 32 and 34 may be formed of the same metal, and may be formed integrally with the first electrode 10 and the second electrode 20. The first and second gate metals 32 and 34 may be formed of one or more metallic materials. The first and second gate metals 32 and 34 may overlap with each other. The dimensions of the first and second gate metals 32 and 34 may be substantially the same as illustrated in FIG. 10.

The semiconductor layer 40 is formed under the first gate metal 32 with the gate oxide layer 60 disposed therebetween. More specifically, the semiconductor layer 40 may have a smaller length in the first direction I-I′ than the first gate metal 32. The semiconductor layer 40 may be positioned substantially centrally below the first gate metal 32 so that side portions of the first gate metal 32 (also referred to as simply the sides of the first gate metal 32) may extend further along the first direction I-I′ than the semiconductor layer 40, so that the first gate metal 32 and the semiconductor layer 40 may form a T shape. The semiconductor layer 40 may be formed of silicon. The drain region 42 is formed in the top of the semiconductor layer 40 corresponding to one side of the first gate metal 32, and the source region 44 is formed in the top of the semiconductor layer 40 corresponding to the other side of the first gate metal 32. The drain region 42 and the source region 44 are formed on both sides of the first gate metal 32 in such a way as to be separated from each other. The first gate metal 32 and the semiconductor layer 40 which is formed with the drain region 42 and the source region 44 may be formed into the structure of an n-type transistor. For instance, in a program operation a ground voltage may be applied to the first electrode 10 and a program voltage may be applied to the second electrode 20.

The first oxide layer 52 is formed under the first and second electrodes 10 and 20, and the second gate metal 34. The first oxide layer is also disposed on both sides of the semiconductor layer 40. The first oxide layer 52 may be formed at the same level as the semiconductor layer 40. The gate oxide layer 60 is formed on the first oxide layer 52 and the semiconductor layer 40.

In this way, in the e-fuse 100, the drain region 42 and the source region 44 may be formed on both sides of the first gate metal 32, and the first oxide layer 52 may be formed on both sides of the second gate metal 34.

In such an e-fuse 100, when the program voltage is applied to the first and second electrodes 10 and 20, program current flows through the gate metal 30 due to a potential difference of the first and second electrodes 10 and 20, and, electro-migration, thermo-migration and melting phenomena may be induced in the gate metal 30 by the program current which may cause the gate metal 30 to blow at the center thereof or at a portion thereof that is close to the second electrode 20. Then, even if an operation voltage is applied to the gate metal 30, the transistor does not operate since a channel is not formed between the drain region 42 and the source region 44.

FIG. 10 is a top view to assist in the explanation of an e-fuse 100 of a semiconductor device in accordance with a third embodiment of the present disclosure. FIG. 11 is a cross-sectional view taken along the line I-I′ of FIG. 10. A silicon nitride layer 70 and a second oxide layer 54 shown in FIG. 11 are not shown in the top view of FIG. 10 to facilitate the understanding of the structure of the present embodiment. As shown in FIG. 11, the silicon nitride layer 70 may be formed on gate metal 30 and first and second electrodes 10 and 20, and the second oxide layer 54 may be formed on the silicon nitride layer 70, the semiconductor layer 40 and the first oxide layer 52.

Referring to FIGS. 10 and 11, the e-fuse 100 of a semiconductor device includes the first and second electrodes 10 and 20, the gate metal 30, the semiconductor layer 40 which is formed with a drain region 42 and a source region 44, the first oxide layer 52 and the gate oxide layer 60.

The gate metal 30 which couples the first and second electrodes 10 and 20 includes first gate metal 32 which extends from the first electrode 10 toward the second electrode 20 and a second gate metal 34 which extends from the second electrode 20 toward the first electrode 10. The first and second gate metals 32 and 34 may be formed of the same metal, and may be formed integrally with the first electrode 10 and the second electrode 20. The first and second gate metals 32 and 34 may be formed of one or more metallic materials. The first and second gate metals 32 and 34 may overlap with each other. The first and second gate metals 32 and 34 may have substantially the same dimensions.

The semiconductor layer 40 is formed under the second gate metal 34 with the gate oxide layer 60 disposed therebetween. More specifically, the semiconductor layer 40 may have a smaller length in the first direction I-I′ than the second gate metal 34. The semiconductor layer 40 may be positioned substantially centrally below the second gate metal 34 so that side portions of the second gate metal 34 (also referred to as simply the sides of the second gate metal 34) may extend further along the first direction I-I′ than the semiconductor layer 40, so that the second gate metal 34 and the semiconductor layer may form a T shape. The semiconductor layer 40 may be formed of silicon. The drain region 42 is formed in the top of the semiconductor layer 40 corresponding to one side of the second gate metal 34, and the source region 44 is formed in the top of the semiconductor layer 40 corresponding to the other side of the second gate metal 34. The drain region 42 and the source region 44 are formed on both sides of the second gate metal 34 in such a way as to be separated from each other. The second gate metal 34 and the semiconductor layer 40 which is formed with the drain region 42 and the source region 44 may be formed into the structure of a p-type transistor. For instance, in a program operation a program voltage may be applied to the first electrode 10 and a ground voltage may be applied to the second electrode 20. Of course, the embodiment is not limited thereto, and, in a program operation the ground voltage may be applied to the first electrode 10 and the program voltage may be applied to the second electrode 20.

The first oxide layer 52 is formed under the first and second electrodes 10 and 20, and the first gate metal 32. The first oxide layer 60 is also disposed on both sides of the semiconductor layer 40. The first oxide layer 52 may be formed at the same level as the semiconductor layer 40. The gate oxide layer 60 is formed on the first oxide layer 52 and the semiconductor layer 40.

In this way, in the e-fuse 100 of a semiconductor device, the drain region 42 and the source region 44 may be formed on both sides of the second gate metal 34, and the first oxide layer 52 may be formed on both sides of the first gate metal 32.

In such an e-fuse 100, when the program voltage is applied to the first and second electrodes 10 and 20, program current flows through the gate metal 30 due to the potential difference of the first and second electrodes 10 and 20, inducing electro-migration, thermo-migration and melting phenomena in the gate metal 30, which may then cause the gate metal 30 to blow at the center thereof or a portion thereof that is close to the first electrode 10. Then, even if an operation voltage is applied to the gate metal 30, the transistor does not operate since a channel is not formed between the drain region 42 and the source region 44.

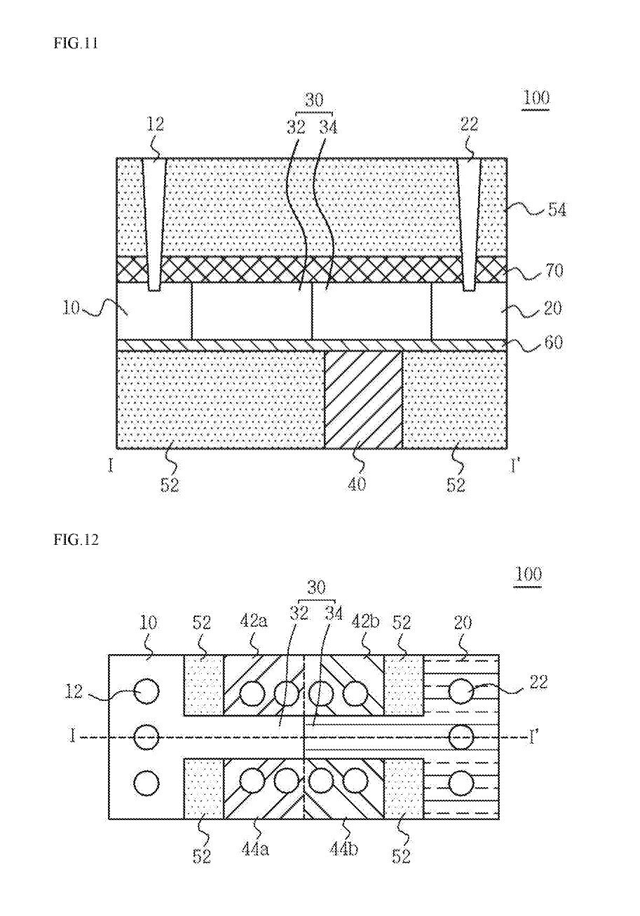

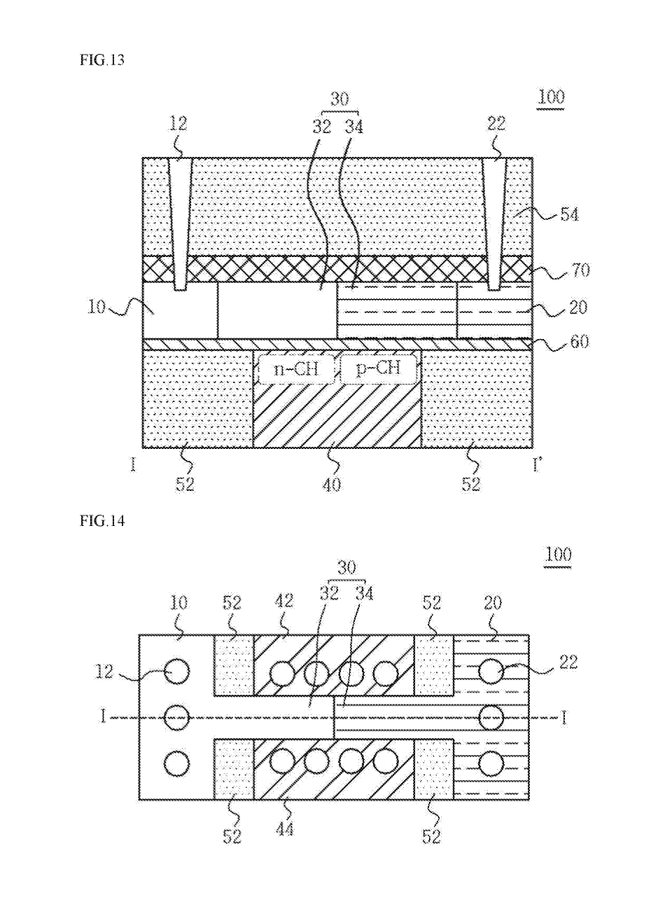

FIG. 12 is a top view to assist in the explanation of an e-fuse 100 of a semiconductor device in accordance with a fourth embodiment of the present disclosure. FIG. 13 is a cross-sectional view taken along the line I-I′ of FIG. 12. A silicon nitride layer 70 and a second oxide layer 54 shown in FIG. 13 are not shown in the top view of FIG. 12 to facilitate the understanding of the structure of the present embodiment. As shown in FIG. 13, the silicon nitride layer 70 may be formed on a gate metal 30 and first and second electrodes 10 and 20, and the second oxide layer 54 may be formed on the silicon nitride layer 70, a semiconductor layer 40 and a first oxide layer 52.

Referring to FIGS. 12 and 13, the e-fuse 100 of a semiconductor device includes the first and second electrodes 10 and 20, the gate metal 30, the semiconductor layer 40 which is formed with a drain region 42 and a source region 44, and the first oxide layer 52.

The first electrode 10 may be referred to as a cathode, and the second electrode 20 may be referred to as an anode. Contacts 12 and 22 for applying a program voltage in program may be formed on the first and second electrodes 10 and 20. The program includes a process of flowing program current through the gate metal 30 by applying a program voltage to any one of the first and second electrodes 10 and 20 and applying a ground voltage to the other of the first and second electrodes 10 and 20.

The gate metal 30 electrically couples the first and second electrodes 10 and 20, and includes a first gate metal 32 which extends from the first electrode 10 toward the second electrode 20 and a second gate metal 34 which extends from the second electrode 20 toward the first electrode 10. The first and second gate metals 32 and 34 may be formed of different metals or may be formed of one or more different metallic materials. For instance, the first gate metal 32 may be formed of a metallic material such as Al, and the second gate metal 34 may be formed of layers of TiN, Ti, Al and AITiO. Alternatively, the first and second gate metals 32 and 34 may be formed of layers of TiN, Ti, Al and AITiO which have different specific gravities. The first gate metal 32 may be formed integrally with the first electrode 10, and the second gate metal 34 may be formed integrally with the second electrode 20. The first and second gate metals 32 and 34 may overlap with each other.

The semiconductor layer 40 is formed under the first and second gate metals 32 and 34 with the gate oxide layer 60 disposed therebetween. The semiconductor layer 40 may have a smaller length in the first direction I-I′ than the metal gate 30 and may be disposed substantially centrally below the gate 30 so that side portions of the gate 30 (sides of the gate 30) extend further along the first direction I-I′ than the semiconductor layer 40. Hence, the metal gate 30 and the semiconductor layer 40 may form a T shape. The semiconductor layer 40 may be formed of silicon. Drain regions 42a and 42b are formed in the top of the semiconductor layer 40 corresponding to one sides of the first and second gate metals 32 and 34, and source regions 44a and 44b are formed in the top of the semiconductor layer 40 corresponding to the other sides of the first and second gate metals 32 and 34. In the semiconductor layer 40, an n-type channel is formed between the drain region 42a and the source region 44a, and a p-type channel is formed between the drain region 42b and the source region 44b.

The drain regions 42a and 42b and the source regions 44a and 44b are formed on both sides of the gate metal 30 in such a way as to be separated from each other. One half of the semiconductor layer 40 which is formed with the drain region 42a and the source region 44a may be formed in an n-type, and the other half of the semiconductor layer 40 which is formed with the drain region 42b and the source region 44b may be formed in a p-type. That is, the first gate metal 32 and one half of the semiconductor layer 40 which is formed with the drain and source regions 42a and 44a form an n-type transistor, and the second gate metal 34 and the other half of the semiconductor layer 40 which is formed with the drain and source regions 42b and 44b form a p-type transistor.

The first oxide layer 52 is formed under the first and second electrodes 10 and 20 and on both sides of the semiconductor layer 40. The first oxide layer 52 may be formed at the same level as the semiconductor layer 40.

The gate oxide layer 60 is formed under the gate metal 30 and the first and second electrodes 10 and 20. The gate oxide layer 60 may be formed to be brought into contact with the semiconductor layer 40 corresponding to the bottom end of the gate metal 30. And the gate oxide layer 60 may be formed to be brought into contact with the top end of the first oxide layer 52 corresponding to the bottom end of the gate metal 30. The gate oxide layer 60 may react with the gate metal 30 or be changed in its dielectric constant characteristic due to a high temperature in the program. For instance, the gate oxide layer 60 may be formed of HfO₂.

The silicon nitride layer 70 is formed on the gate metal 30, and the second oxide layer 54 is formed on the silicon nitride layer 70. For instance, the silicon nitride layer 70 may be formed of SiN or SiCN.

As such, the e-fuse 100 of a semiconductor device includes the first and second gate metals 32 and 34 which electrically couple the first and second electrodes 10 and 20 and are formed of different metals, the semiconductor layer 40 which is formed under the first and second gate metals 32 and 34, is formed with the drain regions 42a and 42b and the source regions 44a and 44b in the top thereof corresponding to both sides of the first and second gate metals 32 and 34 and forms transistors together with the first and second gate metals 32 and 34, the gate oxide layer 60, and the first oxide layer 52 which is formed on both sides of the semiconductor layer 40.

In the e-fuse 100 of a semiconductor device configured as mentioned above, when the program voltage is applied to the first and second electrodes 10 and 20, the program current flows through the gate metal 30 due to the potential difference of the first and second electrodes 10 and 20, and electro-migration, thermo-migration and melting phenomena are induced in the gate metal 30 by the program current. As a result, a void may be formed in the gate metal 30 and resistance may increase.

Also, in the e-fuse 100, the gate metal 30 and the gate oxide layer 60 may react with each other or the dielectric constant characteristic of the gate oxide layer 60 may change due to the high temperature of the gate metal 30 during the programming. Through this, the drain current, gate current and substrate current of the e-fuse 100 significantly change before and after the programming.

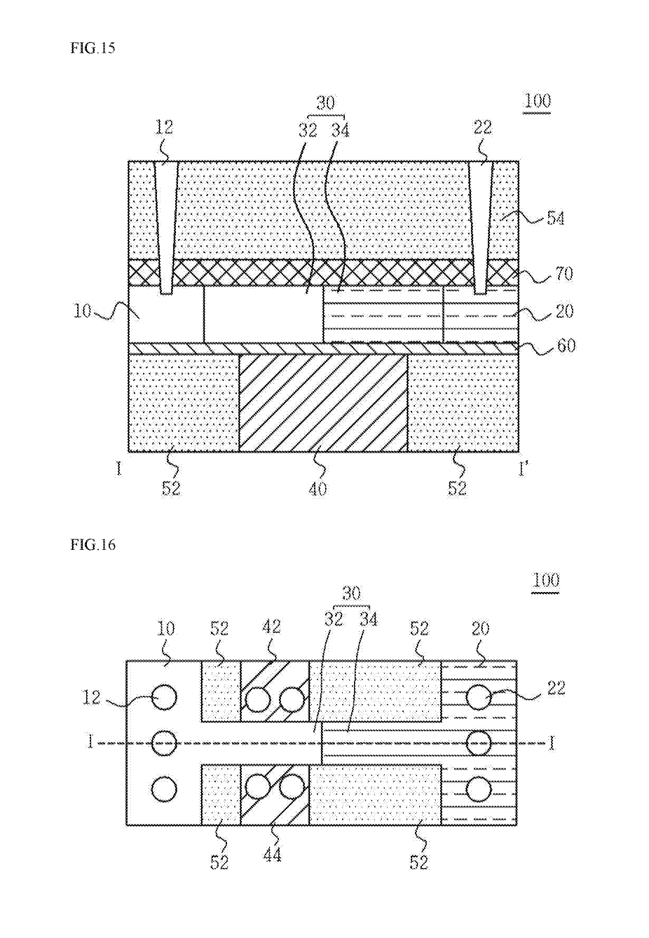

FIG. 14 is a top view to assist in the explanation of an e-fuse 100 of a semiconductor device in accordance with a fifth embodiment of the present disclosure. FIG. 15 is a cross-sectional view taken along the line I-I′ of FIG. 14. A silicon nitride layer 70 and a second oxide layer 54 shown in FIG. 15 are not shown in the top view of FIG. 14 to facilitate the understanding of the structure of the present embodiment. As shown in FIG. 15, the silicon nitride layer 70 may be formed on gate metal 30 and first and second electrodes 10 and 20, and the second oxide layer 54 may be formed on the silicon nitride layer 70, the semiconductor layer 40 and the first oxide layer 52.

Referring to FIGS. 14 and 15, the e-fuse 100 of a semiconductor device includes the first and second electrodes 10 and 20, first and second gate metals 32 and 34 which electrically couple the first and second electrodes 10 and 20 and are formed of different metals, the semiconductor layer 40 which is formed under the first and second gate metals 32 and 34, drain region 42 and source region 44 in the top of the semiconductor layer 40 corresponding to both sides of the first and second gate metals 32 and 34 and forming a transistor together with the first and second gate metals 32 and 34, and a first oxide layer 52 which is formed on both sides of the semiconductor layer 40. The first and second gate metals 32 and 34 and the semiconductor layer 40 which is formed with the drain region 42 and the source region 44 may be formed into the structure of an n-type or a p-type transistor.

In the e-fuse 100 of a semiconductor device configured as mentioned above, the amount of drain current changes due to a change in the width of the transistor, an increase in the resistance of the gate metal 30 and changes in a work function and so forth, and the amounts of gate current and substrate current change due to changes in the characteristics of the gate metal 30 and a gate oxide layer 60 and the breakdown of the gate oxide layer 60, depend on whether or not a program is performed.

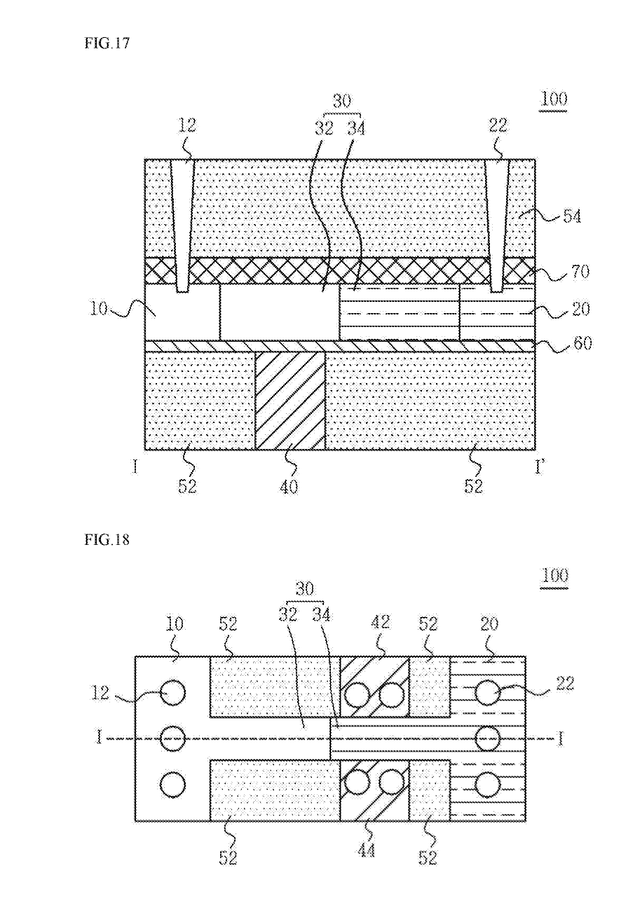

FIG. 16 is a top view to assist in the explanation of an e-fuse 100 of a semiconductor device in accordance with a sixth embodiment of the present disclosure. FIG. 17 is a cross-sectional view taken along the line I-I′ of FIG. 16. A silicon nitride layer 70 and a second oxide layer 54 shown in FIG. 17 are not shown in the top view of FIG. 16 to facilitate the understanding of the structure of the present embodiment. As shown in FIG. 17, the silicon nitride layer 70 may be formed on a gate metal 30 and first and second electrodes 10 and 20, and the second oxide layer 54 may be formed on the silicon nitride layer 70, a semiconductor layer 40 and a first oxide layer 52.

Referring to FIGS. 16 and 17, the e-fuse 100 of a semiconductor device includes first and second gate metals 32 and 34 which electrically couple the first and second electrodes 10 and 20 and are formed of different metals, the semiconductor layer 40 which is formed under the first gate metal 32, is formed with a drain region 42 and a source region 44 in the top thereof corresponding to both sides of the first gate metal 32 and forms a transistor together with the first gate metal 32, and a first oxide layer 52 which is formed under the first and second electrodes 10 and 20, under the second gate metal 34 and on both sides of the semiconductor layer 40.

The first gate metal 32 and the semiconductor layer 40 which is formed with the drain region 42 and the source region 44 may be formed into the structure of an n-type transistor, and a ground voltage may be applied to the first electrode 10 and a program voltage may be applied to the second electrode 20, in program.

In such an e-fuse 100, when the program voltage is applied to the first and second electrodes 10 and 20, program current flows through the gate metal 30 due to the potential difference of the first and second electrodes 10 and 20, inducing electro-migration, thermo-migration and melting phenomena in the gate metal 30 and causing the gate metal 30 to blown at the center thereof or a portion thereof that is close to the second electrode 20. Then, even if an operation voltage is applied to the gate metal 30, the transistor does not operate since a channel is not formed between the drain region 42 and the source region 44.

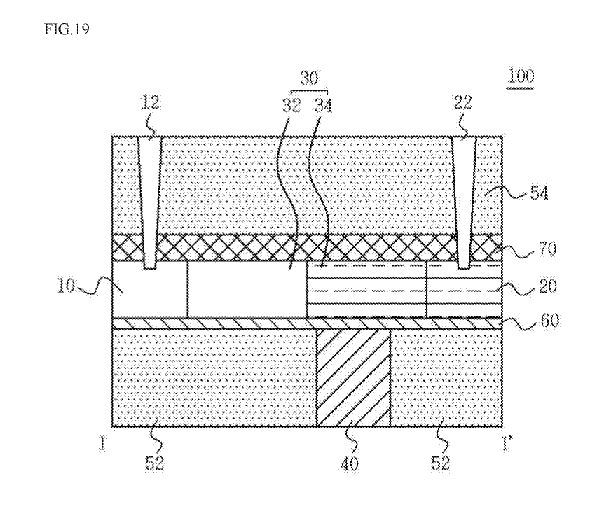

FIG. 18 is a top view to assist in the explanation of an e-fuse 100 of a semiconductor device in accordance with a seventh embodiment of the present disclosure. FIG. 19 is a cross-sectional view taken along the line I-I′ of FIG. 18. A silicon nitride layer 70 and a second oxide layer 54 shown in FIG. 19 are not shown in the top view of FIG. 18 to facilitate the understanding of the structure of the present embodiment. As shown in FIG. 19, the silicon nitride layer 70 may be formed on gate metal 30 and first and second electrodes 10 and 20, and the second oxide layer 54 may be formed on the silicon nitride layer 70, semiconductor layer 40 and first oxide layer 52.

Referring to FIGS. 18 and 19, the e-fuse 100 of a semiconductor device includes first and second gate metals 32 and 34 which electrically couple the first and second electrodes 10 and 20 and are formed of different metals, the semiconductor layer 40 which is formed under the second gate metal 34, is formed with a drain region 42 and a source region 44 in the top thereof corresponding to both sides of the second gate metal 34 and forms a transistor together with the second gate metal 34, and a first oxide layer 52 which is formed under the first and second electrodes 10 and 20, under the first gate metal 32 and on both sides of the semiconductor layer 40.

The second gate metal 34 and the semiconductor layer 40 which is formed with the drain region 42 and the source region 44 may be formed into the structure of a p-type transistor, and a program voltage may be applied to the first electrode 10 and a ground voltage may be applied to the second electrode 20, in program.

In such an e-fuse 100, when the program voltage is applied to the first and second electrodes 10 and 20, program current flows through the gate metal 30 due to the potential difference of the first and second electrodes 10 and 20, inducing electro-migration, thermo-migration and melting phenomena in the gate metal 30 and causing the gate metal 30 to blow at the center thereof or a portion thereof close to the first electrode 10. Then, even if an operation voltage is applied to the gate metal 30, the transistor does not operate since a channel is not formed between the drain region 42 and the source region 44.

Although various embodiments have been described for illustrative purposes, it will be apparent to those skilled in the art that various changes and modifications may be made without departing from the spirit and scope of the invention as defined in the following claims.

What is claimed is:

1. An e-fuse for use in a semiconductor device, comprising:
first and second electrodes;
a gate metal electrically coupling the first and second electrodes with each other;
a semiconductor layer formed under the gate metal, and formed with a drain region and a source region in a top thereof corresponding to both sides of the gate metal to form a transistor together with the gate metal; and
a first oxide layer formed under the gate metal and on both sides of the semiconductor layer.

2. The e-fuse for use in a semiconductor device according to claim 1, further comprising:
a gate oxide layer formed between a bottom end of the gate metal and a top end of the semiconductor layer corresponding to the bottom end of the gate metal.

3. The e-fuse for use in a semiconductor device according to claim 1, further comprising:
a silicon nitride layer formed over the gate metal; and
a second oxide layer formed over the silicon nitride layer, the semiconductor layer and the first oxide layer.

4. The e-fuse of a semiconductor device according to claim 1, wherein the gate metal and the semiconductor layer form an n-type or a p-type transistor.

5. The e-fuse for use in a semiconductor device according to claim 1,
wherein the gate metal includes a first gate metal extending from the first electrode and a second gate metal extending from the second electrode to be contact with the first gate metal, and
wherein the first and second gate metals are formed of the same metal.

6. The e-fuse for use in a semiconductor device according to claim 5, wherein the semiconductor layer is formed under the first gate metal, and is formed with a drain region and a source region in a top thereof corresponding to both sides of the first gate metal to form an n-type transistor together with the first gate metal.

7. The e-fuse for use in a semiconductor device according to claim 6, wherein the first oxide layer is formed under the second gate metal.

8. The e-fuse for use in a semiconductor device according to claim 5, wherein the semiconductor layer is formed under the second gate metal, and is formed with a drain region and a source region in a top thereof corresponding to both sides of the second gate metal to form a p-type transistor together with the second gate metal.

9. The e-fuse for use in a semiconductor device according to claim 8, wherein the first oxide layer is formed under the first gate metal.

10. An e-fuse for use in a semiconductor device, comprising:
first and second electrodes;
a gate metal electrically coupling the first and second electrodes with each other;
a semiconductor layer formed under the gate metal, and formed with a drain region and a source region in a top thereof corresponding to both sides of the gate metal to form a transistor together with the gate metal; and
a first oxide layer formed under a bottom end of the gate metal and on both sides of the semiconductor layer,
wherein the gate metal includes a first gate metal extending from the first electrode and a second gate metal extending from the second electrode to be brought into contact with the first gate metal, and
wherein the first and second gate metals are formed of different metals.

11. The e-fuse for use in a semiconductor device according to claim 10, further comprising:
a gate oxide layer formed between a bottom end of the gate metal and a top end of the semiconductor layer corresponding to the bottom end of the gate metal.

12. The e-fuse for use in a semiconductor device according to claim 10, further comprising:
a silicon nitride layer formed over the gate metal; and
a second oxide layer formed over the silicon nitride layer, the semiconductor layer and the first oxide layer.

13. The e-fuse for use in a semiconductor device according to claim 10,
wherein the first gate metal and one half of the semiconductor layer form an n-type transistor, and
wherein the second gate metal and the other half of the semiconductor layer form a p-type transistor.

14. The e-fuse for use in a semiconductor device according to claim 13, wherein an n-type channel and a p-type channel corresponding to the n-type transistor and the p-type transistor are formed in the semiconductor layer between the drain region and the source region.

15. The e-fuse for use in a semiconductor device according to claim 10, wherein, in program of the e-fuse, a program voltage is applied to any one of the first and second electrodes, and a ground voltage is applied to the other.

16. The e-fuse for use in a semiconductor device according to claim 10, wherein the gate metal and the semiconductor layer form an n-type or a p-type transistor.

17. The e-fuse for use in a semiconductor device according to claim 10, wherein the semiconductor layer is formed under the first gate metal, and is formed with a drain region and a source region in a top thereof corresponding to both sides of the first gate metal to form an n-type transistor together with the first gate metal.

18. The e-fuse for use in a semiconductor device according to claim 17, wherein the first oxide layer is formed under the second gate metal.

19. The e-fuse for use in a semiconductor device according to claim 10, wherein the semiconductor layer is formed under the second gate metal, and is formed with a drain region and a source region in a top thereof corresponding to both sides of the second gate metal to form a p-type transistor together with the second gate metal.

20. The e-fuse for use in a semiconductor device according to claim 19, wherein the first oxide layer is formed under the first gate metal.

21. A semiconductor device,
comprising a plurality of e-fuses, each of the e-fuses comprising:
first and second electrodes;
a gate metal electrically coupling the first and second electrodes with each other;
a semiconductor layer formed under the gate metal, and formed with a drain region and a source region in a top thereof corresponding to both sides of the gate metal to form a transistor together with the gate metal; and
a first oxide layer formed under the gate metal and on both sides of the semiconductor layer.
